(19) United States
(12) Patent Application Publication
(10) Pub. No.: US 2010/0173497 A1
(43) Pub. Date: Jul. 8, 2010

(54) Method of fabricating semiconductor integrated circuit device

(75) Inventors: Chong-Kwang Chang, Bucheon-si (KR); Hong-Jae Shin, Seoul (KR); Nae-In Lee, Seoul (KR); Seo-Woo Nam, Yongin-si (KR); In-Keun Lee, Yongin-si (KR); Jung-Hoon Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/655,837

(22) Filed: Jan. 6, 2010

(30) Foreign Application Priority Data
Jan. 7, 2009 (KR) 10-2009-0001154

(51) Int. Cl. H01L 21/306

(52) U.S. Cl. 438/703; 257/E21.215

(57) ABSTRACT

A method manufacturing a semiconductor integrated circuit device includes providing a substrate; sequentially forming a layer to be etched, a first layer, and a second layer on the substrate; forming on the first and second layers a first etch mask having a plurality of first line patterns separated from each other by a first pitch and extending in a first direction; sequentially performing first etching on the second layer and the first layer using the first etch mask to form an intermediate mask pattern with second and first patterns; forming on the intermediate mask pattern a second etch mask including a plurality of second line patterns separated from each other by a second pitch and extending in a second direction other than the first direction; performing second etching using the second etch mask on a portion of the second pattern so that the remaining portion of the second pattern is left on the first pattern; performing third etching using the second etch mask under different conditions than the second etching on the first pattern and the remaining portion of second pattern of the intermediate mask pattern and forming a final mask pattern; and patterning the layer to be etched using the final mask pattern.

### CROSS-REFERENCE TO RELATED APPLICATION

This application claims priority from Korean Patent Application No. 10-2009-0001154 filed on Jan. 7, 2009 in the Korean Intellectual Property Office, and all the benefits accruing therefrom under 35 U.S.C. 119, the contents of which in its entirety are herein incorporated by reference.

### BACKGROUND

1. Field of the Invention

The present inventive concept relates to a method of fabricating a semiconductor integrated circuit (IC) device.

2. Description of the Related Art

Due to the recent trend toward increasing the integration density of semiconductor integrated circuit (IC) devices, design rules have continued to shrink. As a result, it has become more difficult to form fine patterns in the semiconductor IC devices. With decreasing design rule, it becomes more difficult to adjust the space between gates in a process for manufacturing a semiconductor IC device.

To overcome these problems, a double patterning method has been proposed which includes forming a line pattern in a first direction and a line pattern in a second direction other than the first direction to form a hard mask pattern.

However, this approach has a drawback that an overlapping region where first and second directions intersect each other is double etched to cause damage to a layer to be etched during the double patterning

### SUMMARY

The present inventive concept provides a method of fabricating a semiconductor integrated circuit device with improved reliability.

The above and other objects of the present inventive concept will be described in or be apparent from the following description of the preferred embodiments.

According to an aspect of the present inventive concept, there is provided a method of manufacturing a semiconductor integrated circuit device, the method including providing a substrate; sequentially forming a layer to be etched, a first layer, and a second layer on the substrate; forming on the first and second layers a first etch mask having a plurality of first line patterns separated from each other by a first pitch and extending in a first direction; sequentially performing first etching on the second layer and the first layer using the first etch mask to form an intermediate mask pattern with second and first patterns; forming on the intermediate mask pattern a second etch mask including a plurality of second line patterns separated from each other by a second pitch and extending in a second direction other than the first direction; performing second etching using the second etch mask on a portion of the second pattern so that the remaining portion of the second pattern is left on the first pattern; performing third etching using the second etch mask under different conditions than the second etching on the first pattern and the remaining portion of second pattern of the intermediate mask pattern and forming a final mask pattern; and patterning the layer to be etched using the final mask pattern.

In one embodiment, during the third etching, an etch selectivity of the second pattern with respect to the first pattern is 1.

In one embodiment, the method further comprises, after the forming of the intermediate mask pattern, forming a first sacrificial layer on the intermediate mask pattern.

In one embodiment, the method further comprises, after the performing of second etching on the portion of the second pattern in the intermediate mask pattern, forming a second sacrificial layer on the remaining portion of second pattern.

In one embodiment, the layer to be etched is a polysilicon layer, the first layer is a tetraethylorthosilicate (TEOS) layer, and the second layer is a spin-on hardmask (SOH) layer.

In one embodiment, the forming of the final mask pattern includes forming a plurality of rectangular patterns separated from each other in the first and second directions.

According to another aspect of the present inventive concept, there is provided a method of manufacturing a semiconductor integrated circuit device, the method including providing a substrate; sequentially forming a layer to be etched, a first layer, and a second layer on the substrate; forming on the first and second layers a first etch mask having a plurality of first line patterns separated from each other by a first pitch and extending in a first direction; sequentially performing first etching on the second layer and the first layer using the first etch mask to form an intermediate mask pattern with second and first patterns; forming on the intermediate mask pattern a second etch mask including a plurality of second line patterns separated from each other by a second pitch and extending in a second direction other than the first direction; performing second etching using the second etch mask on the second pattern of the intermediate mask pattern so as to expose a top surface of the first pattern; forming a sacrificial layer on the exposed top surface of the first pattern; performing third etching using the second etch mask under different conditions than the second etching on the sacrificial layer and the first pattern and forming a final mask pattern; and patterning the layer to be etched using the final mask pattern.

In one embodiment, the forming of the sacrificial layer includes covering the exposed first pattern.

In one embodiment, during the third etching, an etch selectivity of the sacrificial layer with respect to the first pattern is 1.

In one embodiment, the forming of the final mask pattern includes forming a plurality of rectangular patterns separated from each other in the first and second directions.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 is a cross-sectional view of an intermediate stack structure provided by steps of a method of fabricating a nonvolatile memory device according to an embodiment of the present inventive concept.

FIG. 2A is a conceptual diagram illustrating a first exposure mask used for forming a first etch mask according to embodiments of the present inventive concept.

FIGS. 2B and 3 are cross-sectional views of intermediate stack structures of the semiconductor IC device taken along lines I-I′ (left side) and II-II′ (right side) of FIG. 2A.

FIG. 4A is a conceptual diagram illustrating a second exposure mask used for forming a second etch mask according to embodiments of the present inventive concept.

FIGS. 4B, 5, and 6 are cross-sectional views of intermediate stack structures of the semiconductor IC device taken along lines I-I′ (left side), II-II′ (center), and III-III′ (right side) of FIG. 4A.

FIG. 7A is a conceptual diagram illustrating a final mask pattern according to embodiments of the present inventive concept.

FIGS. 7B and 8 are cross-sectional views of intermediate stack structures of the semiconductor IC device taken along lines I-I′ (left side), II-II′ (center), and III-III′ (right side) of FIG. 7A.

FIG. 9 is a perspective view of a gate pattern manufactured by a method of fabricating a semiconductor IC device according to an embodiment of the present inventive concept.

FIGS. 10 and 11 are cross-sectional views of intermediate stack structures of the semiconductor IC device taken along lines I-I′ (left side), II-II′ (center), and III-III′ (right side) of FIG. 4A

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this description will be thorough and complete and will fully convey the inventive concept to those skilled in the art, and the present inventive concept will only be defined by the appended claims. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

Spatially relative terms, such as “below,” “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like numbers refer to like elements throughout.

It will be understood that, although the terms first, second, etc. may be used herein to describe various elements, components, and/or sections, these elements, components, and/or sections should not be limited by these terms. These terms are only used to distinguish one element, component or section from another element, component, or section. Thus, a first element, component, or section discussed below could be termed a second element, component, or section without departing from the teachings of the present inventive concept.

Exemplary embodiments of the inventive concept are described herein with reference to cross-section illustrations that are schematic illustrations of idealized exemplary embodiments (and intermediate structures) of the present inventive concept. As such, variations from the shapes of the illustrations as a result, for example, of manufacturing techniques and/or tolerances, are to be expected. Thus, exemplary embodiments of the present inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

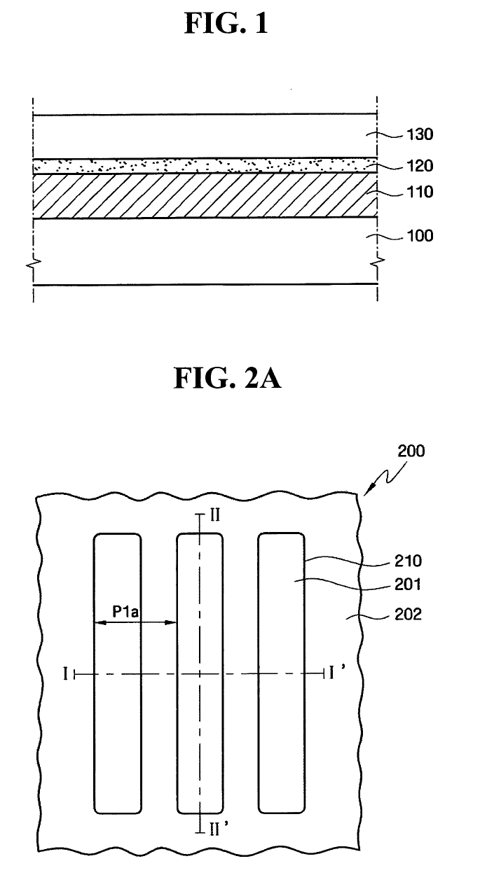

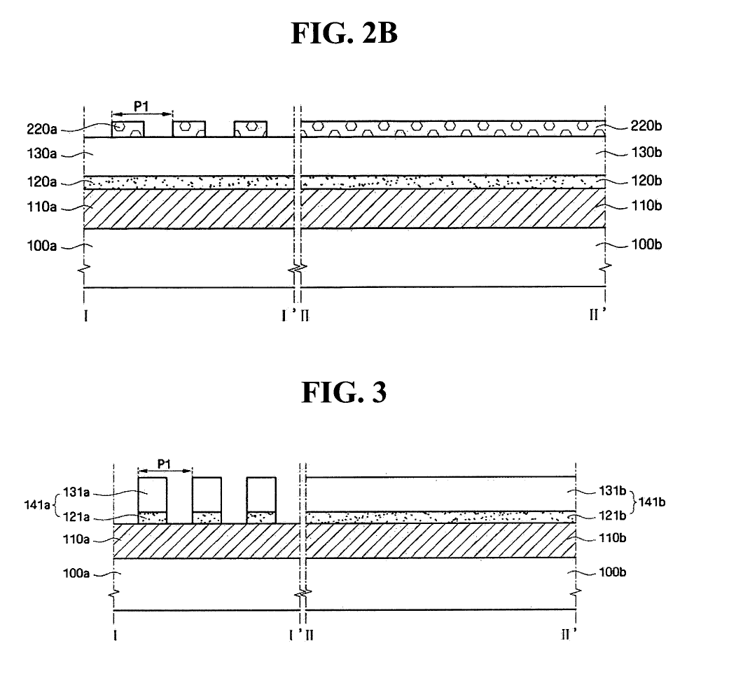

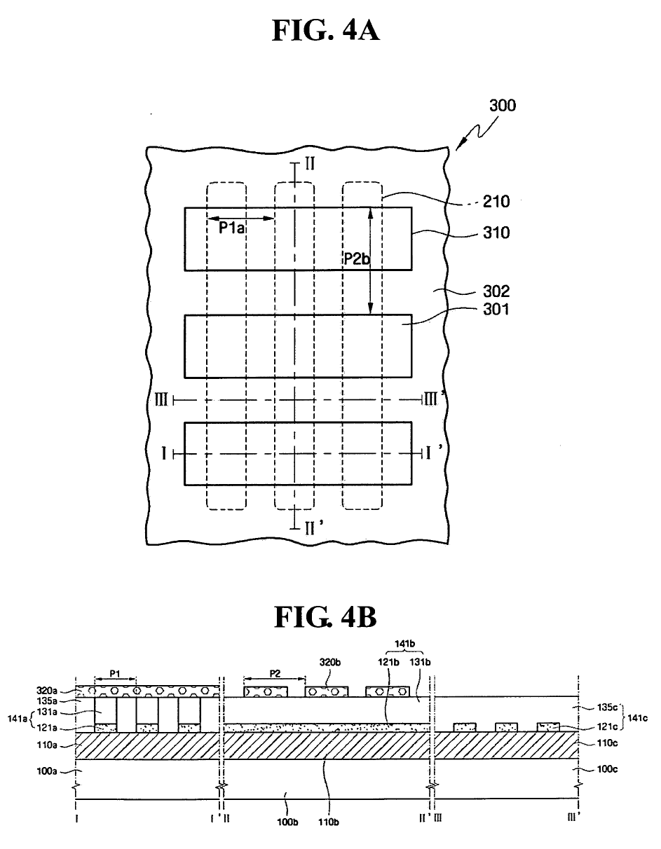

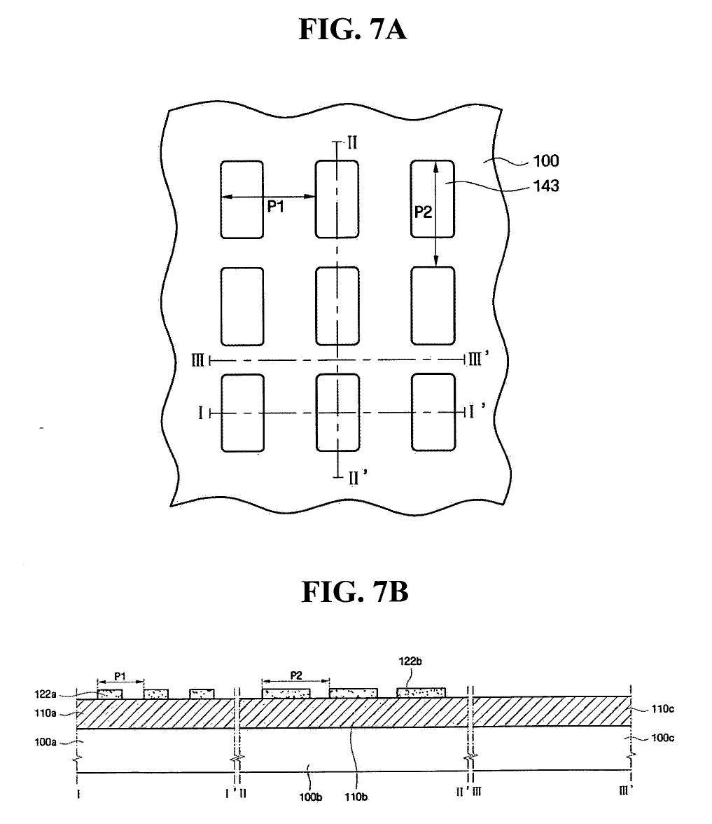

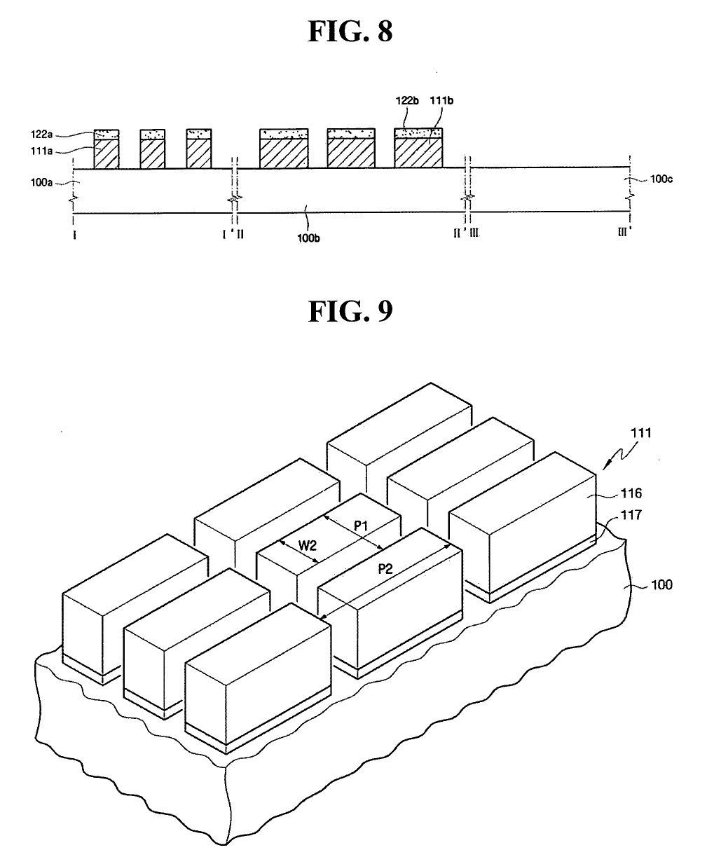

FIG. 1 is a cross-sectional view of an intermediate stack structure provided by steps of a method of fabricating a nonvolatile memory device according to an embodiment of the present inventive concept. FIG. 2A is a conceptual diagram illustrating a first exposure mask used for forming a first etch mask according to embodiments of the present inventive concept. FIGS. 2B and 3 are cross-sectional views of intermediate stack structures of the semiconductor IC device taken along lines I-I′ (left side) and II-II′ (right side) of FIG. 2A. FIG. 4A is a conceptual diagram illustrating a second exposure mask used for forming a second etch mask according to embodiments of the present inventive concept. FIGS. 4B, 5, and 6 are cross-sectional views of intermediate stack structures of the semiconductor IC device taken along lines I-I′ (left side), II-II-′ (center), and III-III′ (right side) of FIG. 4A. FIG. 7A is a conceptual diagram illustrating a final mask pattern according to embodiments of the present inventive concept. FIGS. 7B and 8 are cross-sectional views of intermediate stack structures of the semiconductor IC device taken along lines I-I′ (left side), II-II′ (center), and III-III′ (right side) of FIG. 7A. FIG. 9 is a perspective view of a gate pattern manufactured by a method of fabricating a semiconductor IC device according to an embodiment of the present inventive concept.

Referring to FIG. 1, a semiconductor substrate 100 is provided. A layer 110 to be etched, a first layer 120, and a second layer 130 are sequentially formed on the semiconductor substrate 100. The semiconductor substrate 100 may be a substrate, such as Silicon On Insulator (SOI) substrate, made of at least one semiconductor material that is selected from the group including Si, germanium (Ge), SiGe, gallium phosphide (GaP), gallium arsenide (GaAs), silicon carbide (SiC), SiGeC, indium arsenide (InAs), and InP. The present inventive concept is not limited thereto, and the semiconductor substrate may be made of other materials depending on the application. The layer 110 to be etched is formed over the semiconductor substrate 100. For example, the layer 110 to be etched 110 may be a polysilicon layer. The layer 110 to be etched may be formed by deposition such as chemical vapor deposition (CVD). The first layer 120 and the second layer 130 are sequentially formed on the layer 110 to be etched. For example, the first layer 120 may be tetraethylorthosilicate (TEOS) layer. The second layer 130 may be a spin-on mask layer. Although not shown in the drawings, an anti-reflective layer may overlie the second layer 130.

Referring to FIGS. 2A and 2B, a first etch mask 220a (220b), each including a plurality of first line patterns, is formed on the second layer 130a (130b). The plurality of first line patterns are separated from each other by a first pitch P1 and extend in a first direction. More specifically, an etch mask material is applied over the semiconductor substrate having the first layer 120a (120b) and the second layer 130a (130b) sequentially formed thereon and then subjected to photolithography to form the first etch mask 220a (220b). For example, the etch mask material may be photoresist.

Referring to FIG. 2A, during the photolithography process, the etch mask material may be selectively removed using a first exposure mask 200. The first exposure mask 200 includes a plurality of first exposure patterns 210 corresponding to the plurality of first line patterns in the first etch mask 220a (220b) that will overlie the second layer 130a (130b). The plurality of first exposure patterns 210 have an exposure pitch P1a corresponding to the first pitch P1 of the plurality of first line patterns.

The first exposure mask 200 includes a first region 201 corresponding to a region having the plurality of first line patterns therein and a second region 202 corresponding to the remaining region. The plurality of first exposure patterns 210 may be defined by the first and second regions 201 and 202. For example, if a positive photoresist is used as the etch mask material, the first region 201 and the second region 202 may be a light blocking region and a light transmitting region, respectively. The positive photoresist is a type of photoresist in which a portion of the photoresist exposed to light is removed during development. Conversely, if a negative photoresist (with unexposed portion removed during development) is used as the etch mask material, the first region 201 and the second region 202 may be a light transmitting region and a light blocking region, respectively.

A photolithography process is then performed using the first exposure mask 200 to form the first etch mask 220a having the plurality of first line patterns, as shown on the left side of FIG. 2B. The plurality of first line patterns extend in the first direction and are spaced apart at the first pitch P1. That is, the plurality of first line patterns are repeatedly arranged and spaced a given interval apart from adjacent patterns. In this case, the first pitch P1 of the first etch mask 220a may be adjusted by controlling the exposure pitch P1a of the plurality of first exposure patterns 210.

The first pitch P1 may also represent the distance from one line pattern to another adjacent line pattern. For example, as shown in FIG. 2B, the first etch mask 220a may have a plurality of first line patterns repeatedly arranged at a distance from one sidewall of a line pattern to a sidewall of its adjacent line pattern in the same direction. The first etch mask 220a is not limited thereto, and may have a plurality of first line patterns that are different from each other or arranged at a distance that is other than the first pitch P1 between the sidewalls of adjacent line patterns in the same direction. That is, the first pitch P1 may be the distance from one sidewall of one line pattern to the other sidewall or the center of another line pattern.

As shown on the right side of FIG. 2B, a layer 110b to be etched, a first layer 120b, a second layer 130b, and a first etch mask 220b are sequentially formed over a semiconductor substrate 100b. Because the plurality of first line patterns extend in the first direction that is the same as line II-II′ of FIG. 2A, the right side of FIG. 2B shows a cross-section of an intermediate stack structure taken along the line II-II′ of FIG. 2A in which the first etch mask 220b covers the second layer 130b.

Referring to FIG. 3, first etching is sequentially performed on the second layer (130a and 130b of FIG. 2B) and the first layer (120a and 120b of FIG. 2B) using the first etch mask (220a and 220b of FIG. 2B) to form an intermediate mask pattern 141a (141b) containing a first pattern 121a (121b) and a second pattern 131a (131b). More specifically, the first etching is carried out using the first etch mask 220a (220b) to form the intermediate mask pattern 141a (141b). For example, the first etching may be anisotropic etching

After the first etching, the second layer 130a (130b) and the first layer 120a (120b) are removed using the first etch mask 220a (220b) so that the intermediate mask pattern 141a (141b) correspond to the plurality of first line patterns in the first etch mask 220a (220b). That is, the intermediate mask pattern 141a (141b) may also have a plurality of first line patterns.

As shown on the left side of FIG. 3, each of the plurality of first line patterns in the intermediate mask pattern 141a is spaced apart from its adjacent first line pattern by the first pitch P1. As shown on the right side of FIG. 3, the second pattern 131b and the first pattern 121b remain intact, being protected from etching by the first etch mask 220b. The first etch mask 220a (220b) overlying the intermediate mask pattern 141a (141b) is subsequently removed.

Referring to FIGS. 4A and 4B, a second etch mask 320a (320b) having a plurality of second line patterns therein is formed on the intermediate mask pattern 141a (141b and 141c). The plurality of second line patterns are separated from each other by a second pitch P2 and extend in a second direction other than the first direction. More specifically, an etch mask material such as photoresist is applied over a substrate 100a, 100b, and 100c having the intermediate mask pattern 141a, 141b, and 141c formed thereon and then subjected to photolithography to form the second etch mask 320a and 320b.

Referring to FIG. 4A, similar to forming the first etch mask (220a and 220b of FIG. 2B), a photolithography process is performed using a second exposure mask 300 to selectively remove an etch mask material, thereby forming the second etch mask 320a and 320b. The second exposure mask 300 also includes a plurality of second exposure patterns 310 that are spaced apart by an exposure pitch P2b corresponding to the second pitch P2 of the plurality of second line patterns. Similar to the first line patterns described above, the plurality of second line patterns are spaced apart at the second pitch P2, which means the plurality of patterns are repeatedly arranged at the same interval between adjacent patterns. The second exposure mask 300 includes a first region 301 corresponding to a region having the plurality of second line patterns therein and a second region 302 corresponding to the remaining region. For example, if a positive photoresist is used as the etch mask material, the first region 301 and the second region 302 may be a light blocking region and a light transmitting region, respectively.

As shown in FIG. 4B, the photolithography process is performed using the second exposure mask 300 to form the second etch mask 320a (320b) having the plurality of second line patterns. The plurality of second line patterns are spaced apart by the second pitch P2 and extend in the second direction other than the first direction. As shown in FIG. 4A, the second direction may be perpendicular to the first direction. Further, the second pitch P2 of the second etch mask 320a (320b) may be adjusted by controlling the exposure pitch P2b of the plurality of second exposure patterns 310.

After forming the intermediate mask pattern 141a (141b), a first sacrificial layer 135a (135c) is formed on the intermediate mask pattern 141a (141b). The first sacrificial layer 135a (135c) may be a spin-on hard mask layer formed of the same material as the second layer (130 of FIG. 1). Referring to FIG. 4B, the first sacrificial layer 135a (135c) fills the layer 110a (110b) to be etched that is exposed by the intermediate mask pattern 141a (141b). For example, the first sacrificial layer 135a (135c) may be formed to fill a separation region between the plurality of first line patterns in the intermediate mask pattern 141a (141b) and then subjected to planarization.

When the second etch mask 320a (320b) including the plurality of second line patterns is formed on the intermediate mask pattern 141a (141b) and the first sacrificial layer 135a (135c), arrangement among the intermediate mask pattern 141a (141b), the first sacrificial layer 135a (135c), and the second etch mask 320a (320b) is described with reference to FIG. 4B. More specifically, as shown on the left side of FIG. 4B, the second etch mask 320a is formed on the intermediate mask pattern 141a having the plurality of first line patterns spaced apart by the first pitch P1 and the first sacrificial layer 135a. As shown in the center of FIG. 4B, the second etch mask 320b is formed on the intermediate mask pattern 141b to have a second pitch P2. As shown on the right side of FIG. 4B, the first sacrificial layer 135c overlies the first pattern 121c that is the intermediate mask pattern having the first pitch P1 and is exposed. For example, if a positive photoresist is used, an etch mask material corresponding to a light transmitting region (302 of FIG. 4A) of the second exposure mask (300 of FIG. 4A) may be removed to expose the first sacrificial layer 135c having the first pattern 121c formed thereon.

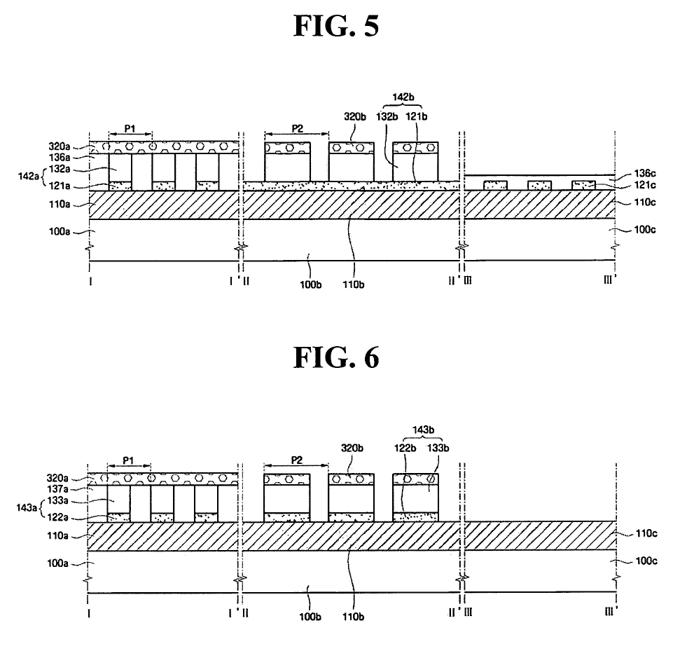

Referring to FIG. 5, second etching is performed on portions of a second pattern 132a and 132b and first sacrificial layer 136c using the second etch mask 320a and 320b so that residues of the second pattern 132a and 132b and first sacrificial layer 136a and 136c remain on the first pattern 121a, 121b, and 121c, respectively. More specifically, the second etching may be anisotropic etching using the second etch mask 320a and 320b. For example, the second etching may be carried out not to expose the first pattern 121a, 121b, and 121c while removing a portion of the second pattern 132a and 132b. Alternatively, the second etching may be performed not to expose the first pattern 121a, 121b, and 121c by removing portions of the second pattern 132a and 132b and first sacrificial layer 136c.

As shown on the left side of FIG. 5, the intermediate mask pattern 142a and the first sacrificial layer 136a filling the separation region between the plurality of first line patterns in the intermediate mask pattern 141a are protected from etching by the second etch mask 320a so that the intermediate mask pattern 142a having the first pitch P1 remains in place.

As shown in the center of FIG. 5, a portion of the second pattern 132b in the intermediate mask pattern 142b is removed using the second etch mask 320b so as to align the intermediate mask pattern 142b to the second pitch P2 of the second etch mask 320b.

As shown on the right side of FIG. 5, a portion of the second sacrificial layer 236c exposed by a gap between the plurality of second line patterns is removed. In this case, the plurality of first line patterns in the first etch mask 220a and 220b are separated by the first pitch P1 and extend in the first direction while the plurality of second line patterns in the second etch mask 320a and 320b are separated by the second pitch P2 and extend in the second direction. Thus, the intermediate mask pattern 141a and 141b intersect the second etch mask 320a and 320b. That is, the first sacrificial layer 136c exposed by the gap between the plurality of second line patterns in the second etch mask 320a and 320b is removed by the second etching. As described above, if the first sacrificial layer 136c is formed of the same material as the second layer 130, the first sacrificial layer 136c and the second pattern 132b may be removed together by the second etching.

During the second etching, a portion of each second pattern 132a and 132b of the intermediate mask pattern 141a and 141b overlying the first pattern 121a and 121b may be removed. That is, if a surface of the second pattern 132b contacting the first pattern 121b and a surface of the second pattern 132b exposed by the second etch mask 320b are called a bottom surface and a top surface of the second pattern 121b, respectively, the top surface of the second pattern 132b is continuously etched before exposing the bottom surface of the second pattern 132b. Similarly, except for the first sacrificial layer 136a protected by the second etch mask 320a, a top surface of the first sacrificial layer 136c exposed by the gap between the second line patterns in the second etch mask 320c is continuously etched to remove the first sacrificial layer 136c before exposing a bottom surface of the first sacrificial layer 136c overlying the first pattern 121c.

Referring to FIG. 6, third etching is thereafter performed using the second etch mask 320a and 320b under different conditions than the second etching to remove a residue of the second pattern (132b of FIG. 5) in an intermediate mask pattern 143a and 143b, the first sacrificial layer (136c of FIG. 5), and the first pattern (121b and 121c of FIG. 5).

More specifically, the third etching is carried out under a process condition in which an etch selectivity of the second pattern 132b with respect to the first pattern 122a, 122b, and 122c is 1. That is, under the same process conditions, the first pattern 122a, 122b, and 122c and the second pattern 132b are etched at the same rate. Thus, the third etching is performed to etch the residue of the second pattern 132b and the first pattern 121b and 121c at the same rate, so that the layer 110b and 110c to be etched is exposed together by a final mask pattern 143b.

As described above, if the first sacrificial layer 136c is formed of the same material as the second pattern 132b, residues of the second pattern 132b and first sacrificial layer 136c and the first pattern 121c can be removed at the same rate by the third etching.

Referring to FIGS. 7A and 7B, the second etch mask (320a and 320b of FIG. 6), second pattern (133a and 133b of FIG. 6), and first sacrificial layer (137a of FIG. 6) are removed by ashing to form a final mask pattern 122a and 122b.

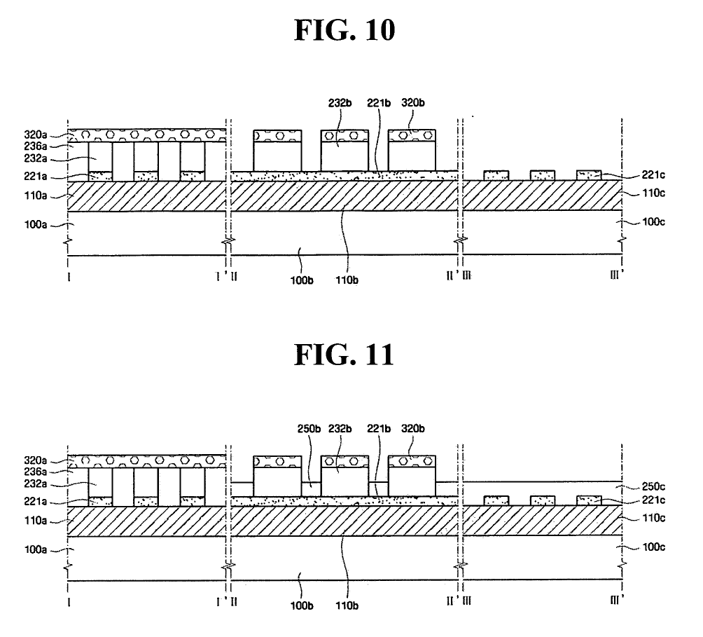

As shown in FIG. 7A, the final mask pattern 122a and 122b may have a plurality of rectangular patterns separated in first and second directions, respectively. For example, each of the plurality of rectangular patterns is separated in the first direction by a second pitch P2 and in the second direction by a first pitch P1. Referring to FIG. 7B, the final mask pattern 122a and 122b is separated in the second direction by the first pitch P1 and in the first direction by the second pitch P2. Subsequently, the layer 110a, 110b, and 110c to be etched is patterned using the final mask pattern 122a and 122b. Thus, the first and second pitches P1 and P2 of the final mask pattern 122a and 122b can be adjusted to determine a space between gate structures that will be formed by patterning the layer 110a, 110b, and 110c to be etched. Although FIGS. 7A and 7B show the first pitch P1 is different from the second pitch P2, they may be equal to each other. Although not shown in the drawings, after performing the second etching on portions of the second pattern 132b and first sacrificial layer 136c, a second sacrificial layer is formed on a residue of the second pattern 132b, followed by removal of the first sacrificial layer 136c, the second sacrificial layer, and the residue of second pattern 132b, and the first pattern 121c with the same etch selectivity. Formation and removal of a sacrificial layer will be described in more detail below with reference to FIGS. 10 and 11.

Referring to FIGS. 8 and 9, the layer 110a, 110b, and 110c to be etched is then patterned using the final mask pattern 122a and 122b. More specifically, the layer 110a, 110b, and 110c to be etched is anisotropically etched using the final mask pattern 122a and 122b as an etch mask.

Referring to FIG. 8, the layer 110a, 110b, and 110c to be etched is etched so that it is aligned to the final mask pattern 122a and 122b to form an etched pattern 111a and 111b. In this case, the etched pattern 111a (111b) is aligned to a sidewall of the final mask pattern 122a (122b).

Referring to FIG. 9, an etched pattern 111 has a plurality of rectangular patterns. Each of the rectangular patterns includes a gate insulating layer 117 and a gate conductive layer 116. The plurality of rectangular patterns are separated from each other in the first direction by a second pitch P2 and in the second direction by a first pitch P1. Although not shown in the drawings, subsequent processes are performed to manufacture a semiconductor IC device.

A method of fabricating a semiconductor IC device according to another embodiment of the present inventive concept is described with reference to FIGS. 10 and 11. The fabrication method according to the current embodiment is different from the method according to the previous embodiment in that the method includes performing second etching on a second pattern of an intermediate mask pattern and forming a sacrificial layer on a first pattern.

FIGS. 10 and 11 are cross-sectional views of intermediate stack structures of the semiconductor IC device taken along lines I-I′ (left side), II-II′ (center), and III-III′ (right side) of FIG. 4A. Descriptions of elements substantially having the same construction as their counterparts in the semiconductor IC device manufactured according to the previous embodiment will not be repeated.

As described above, referring to FIGS. 1, 2A, 2B, 3, 4A, and 4B, the method of fabricating the semiconductor IC device includes providing a substrate, sequentially forming a layer to be etched, a first layer, and a second layer on the substrate, forming on the first and second layers a first etch mask having a plurality of first line patterns separated by a first pitch and extending in a first direction, sequentially performing first etching on the second layer and the first layer using the first etch mask to form an intermediate mask pattern with second and first patterns, and forming on the intermediate mask pattern a second etch mask including a plurality of second line patterns separated by a second pitch and extending in a second direction other than the first direction. In the following description, fabrication steps subsequent to forming the second etch mask are described.

Referring to FIG. 10, second etching is performed on a second pattern 232b of an intermediate mask pattern 242b using the second etch mask 320a and 320b to expose a top surface of a first pattern 221b. More specifically, anisotropic etching is performed using the second etch mask 320a and 320b to remove the second pattern 232b and expose the top surface of the first pattern 221b.

Referring to FIG. 11, a sacrificial layer 250b and 250c is formed on the exposed top surface of the first pattern 221b and the exposed first pattern 221c so as to cover them.

The sacrificial layer 250b and 250c is formed of a material having excellent gapfill characteristics such as spin-on hardmask (SOH), near frictionless carbon (NFC), and bottom anti-reflective coating (BARC) having an excellent planarization property, and is not limited thereto.

Under different conditions than the second etching, third etching is subsequently performed on the sacrificial layer 250b and 250c and the first pattern 221c to form the final mask pattern 122a and 122b as shown in FIG. 7B. More specifically, the third etching is carried out under a process condition in which an etch selectivity of the sacrificial layer 250b and 250c with respect to the first pattern 221b and 221c is 1. That is, under the same process conditions, the first pattern 221b and 221c and the sacrificial layer 250b and 250c are etched at the same rate. Thus, the third etching is carried out to etch the sacrificial layer 250b and 250c and the first pattern 221b and 221c at the same rate. After the third etching, the layer 110b and 110c to be etched protected by the sacrificial layer 250b and 250c and the first pattern 221b and 221c is exposed together. That is, a top surface of a portion of the layer 110b and 110c to be etched protected by the sacrificial layer 250b and 250c is exposed together with a portion of a top surface thereof protected by the first pattern 221b and 221c.

Since the fabrication method according to the current embodiment includes substantially the same subsequent processes as those in the previous embodiment, a detailed description thereof will not be repeated.

According to the fabrication method of the current embodiment, a sacrificial layer is formed on an intermediate mask pattern, followed by etching of the sacrificial layer and the first pattern. Thus, this method prevents damage to a layer to be etched, compared to separate etching of first and second patterns, thereby providing a semiconductor IC device with improved reliability.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive.

What is claimed is:

1. A method of manufacturing a semiconductor integrated circuit device, comprising:
providing a substrate;
sequentially forming a layer to be etched, a first layer, and a second layer on the substrate;
forming on the first and second layers a first etch mask having a plurality of first line patterns separated from each other by a first pitch and extending in a first direction;
sequentially performing first etching on the second layer and the first layer using the first etch mask to form an intermediate mask pattern with second and first patterns;
forming on the intermediate mask pattern a second etch mask including a plurality of second line patterns separated from each other by a second pitch and extending in a second direction other than the first direction;
performing second etching using the second etch mask on a portion of the second pattern so that the remaining portion of the second pattern is left on the first pattern;
performing third etching using the second etch mask under different conditions than the second etching on the first pattern and the remaining portion of second pattern of the intermediate mask pattern and forming a final mask pattern; and
patterning the layer to be etched using the final mask pattern.

2. The method of claim 1, wherein during the third etching, an etch selectivity of the second pattern with respect to the first pattern is 1.

3. The method of claim 1, after the forming of the intermediate mask pattern, further comprising forming a first sacrificial layer on the intermediate mask pattern

4. The method of claim 3, after the performing of second etching on the portion of the second pattern in the intermediate mask pattern, further comprising forming a second sacrificial layer on the remaining portion of second pattern.

5. The method of claim 1, wherein the layer to be etched is a polysilicon layer, the first layer is a tetraethylorthosilicate (TEOS) layer, and the second layer is a spin-on hardmask (SOH) layer.

6. The method of claim 1, wherein the forming of the final mask pattern includes forming a plurality of rectangular patterns separated from each other in the first and second directions.

7. A method of manufacturing a semiconductor integrated circuit device, comprising:
providing a substrate;
sequentially forming a layer to be etched, a first layer, and a second layer on the substrate;
forming on the first and second layers a first etch mask having a plurality of first line patterns separated from each other by a first pitch and extending in a first direction;
sequentially performing first etching on the second layer and the first layer using the first etch mask to form an intermediate mask pattern with second and first patterns;
forming on the intermediate mask pattern a second etch mask including a plurality of second line patterns separated from each other by a second pitch and extending in a second direction other than the first direction;
performing second etching using the second etch mask on the second pattern of the intermediate mask pattern so as to expose a top surface of the first pattern;
forming a sacrificial layer on the exposed top surface of the first pattern;
performing third etching using the second etch mask under different conditions than the second etching on the sacrificial layer and the first pattern and forming a final mask pattern; and
patterning the layer to be etched using the final mask pattern.

8. The method of claim 7, wherein the forming of the sacrificial layer includes covering the exposed first pattern.

9. The method of claim 8, wherein during the third etching, an etch selectivity of the sacrificial layer with respect to the first pattern is 1.

10. The method of claim 7, wherein the forming of the final mask pattern includes forming a plurality of rectangular patterns separated from each other in the first and second directions.
